(19) United States
(12) Patent Application Publication
(10) Pub. No.: US 2011/0194181 A1
(43) Pub. Date: Aug. 11, 2011

(54) FILM FORMING METHOD FOR ANTIREFLECTION FILM, ANTIREFLECTION FILM, AND FILM FORMING DEVICE

(75) Inventors: Hirohisa Takahashi, Sammu-shi (JP); Satoru Ishibashi, Sammu-shi (JP); Haruhiko Yamamoto, Chigasaki-shi (JP); Hidenori Yanagitsubo, Chigasaki-shi (JP)

(73) Assignee: ULVAC, Inc., Chigasaki-shi, Kanagawa (JP)

(21) Appl. No.: 13/123,624

(22) PCT Filed: Oct. 14, 2009
(86) PCT No.: PCT/JP2009/005368

§ 371 Date: Apr. 11, 2011

(30) Foreign Application Priority Data
Oct. 17, 2008 (JP) 2008-268769

(51) Int. Cl. G02B 1/11; C23C 14/08; C23C 14/34; C23C 14/50

(52) U.S. Cl. 359/585; 204/192.26; 204/298.02; 204/298.16; 204/298.15

(57) ABSTRACT

A film forming method for an antireflection film that has a first indium oxide-based thin film and a second indium oxide-based thin film that is laminated on the first indium oxide-based thin film, including a first film forming step that forms the first indium oxide-based thin film by performing sputtering using a first indium oxide-based target in a first reactive gas that contains one, two, or three types selected from a group consisting of oxygen gas, hydrogen gas, and water vapor; and a second film forming step that forms on the first indium oxide-based thin film the second indium oxide-based thin film by performing sputtering using a second indium oxide-based target in a second reactive gas that contains one, two, or three types selected from a group consisting of oxygen gas, hydrogen gas, and water vapor, and that has a different composition from the first reactive gas.

### TECHNICAL FIELD

The present invention relates to a film forming method for an antireflection film, an antireflection film, and a film forming device, and in more detail to a film forming method for an antireflection film, an antireflection film, and a film forming device that are suitably used in the display surface of a flat panel display, the operation surface of a touch panel and the like, and the light receiving surface of a photovoltaic cell.

Priority is claimed on Japanese Patent Application No. 2008-268769, filed Oct. 17, 2008, the content of which is incorporated herein by reference.

### BACKGROUND ART

In recent years, various antireflection films for antireflection have been used in flat panel displays, touch panels, photovoltaic cells, and the like.

As an antireflection film that has conventionally been used, a multi-layer structure antireflection film has been proposed in which a high refractive index layer and a low refractive index layer are laminated in turn on a transparent substrate.

In this kind of antireflection film, for example, TiO₂ (refractive index: 2.3 to 2.55) or ZrO₂ (refractive index: 2.05 to 2.15) is used as the high refractive index layer, and for example SiO₂ (refractive index: 1.45 to 1.46) and the like is used as the low refractive index layer (refer to Patent Documents 1 and 2).

In this kind of antireflection film, it is possible to obtain the desired antireflection performance by changing the thickness and material of the high refractive index layer and the low refractive index layer.

This kind of antireflection film can be obtained by forming on a transparent substrate the low refractive index layer by sputtering using a target made of a low refractive index material such as SiO₂, and then forming on this low refractive index layer the high refractive index layer by sputtering using a target made of a high refractive index material such as TiO₂ or ZrO₂.

### PRIOR ART DOCUMENTS

### Patent Documents

[Patent Document 1] Japanese Unexamined Patent Application, First Publication No. H07-130307
[Patent Document 2] Japanese Unexamined Patent Application, First Publication No. H08-75902

### DISCLOSURE OF THE INVENTION

### Problems to be Solved by the Invention

In order to form a conventional multilayer antireflection film by sputtering, the film formation must be performed with a different target prepared for each layer. That is, the film formation must be performed by sequentially sputtering with a TiO₂ target and an SiO₂ target, or the film formation must be performed by sequentially sputtering with a Ti target and an Si target while introducing a reactive gas such as oxygen gas.

In the case of performing film formation by sputtering with a Ti target and an Si target while introducing a reactive gas such as oxygen gas, since it is necessary to introduce a large amount of oxygen gas, there has been the problem of not being able to perform film formation in the same atmosphere as the atmosphere of forming a transparent electrically conductive film that consists of a metallic oxide.

The present invention was achieved in order to solve the aforementioned problems, and has as its object to provide a film forming method for an antireflection film that is capable of obtaining an indium oxide-based antireflection film that has the desired antireflection performance and that functions as a transparent electrically conductive film by performing sputtering in the same film forming chamber, without involving the bringing in of a substrate to a film forming chamber that performs sputtering and the bringing out of the substrate from the same film forming chamber.

Also, it has as its object to provide an indium oxide-based antireflection film that has the desired antireflection performance and that functions as a transparent electrically conductive film.

Also, it has as an object to provide a film forming device that is capable of forming with one device an antireflection film in which a plurality of refractive index layers with mutually differing refractive indices are laminated. Moreover, it has as an object to provide a film forming device that can form an antireflection film in which a plurality of refractive index layers with mutually differing refractive indices are laminated by using the same indium oxide-based target and sputtering by adjusting the partial pressure of the oxygen gas, hydrogen gas or water vapor that are introduced.

### Means for Solving the Problem

The present inventors have arrived at the present invention as a result of concerted study of a film forming method for an antireflection film that uses an indium oxide-based transparent electrically conductive film, with the discovery that, when forming an indium oxide-based transparent electrically conductive film that consists of laminating a plurality of refractive index layers with different refractive indices by a sputtering method using a target that consists of indium oxide, if the sputtering is performed by changing the proportion of each gas in a reactive gas that contains one, two, or three types selected from a group consisting of oxygen gas, hydrogen gas, and water vapor, it is possible to efficiently form an antireflection film in which on a first indium oxide-based thin film is laminated a second indium oxide-based thin film with a different refraction index and having the desired antireflection performance.

In particular, a film forming method for an antireflection film according to an aspect of the present invention is a film forming method for an antireflection film that has a first indium oxide-based thin film and a second indium oxide-based thin film that is laminated on the first indium oxide-based thin film, the method including: a first film forming step that forms the first indium oxide-based thin film by performing sputtering using a first indium oxide-based target in a first reactive gas that contains one, two, or three types selected from a group consisting of oxygen gas, hydrogen gas, and water vapor; and a second film forming step that forms on the first indium oxide-based thin film the second indium oxide-based thin film by performing sputtering using a second indium oxide-based target in a second reactive gas that contains one, two, or three types selected from a group consisting of oxygen gas, hydrogen gas, and water vapor, and that has a different composition from the first reactive gas.

In the aforementioned manufacturing method, the first indium oxide-based thin film is formed in the first film forming step by performing sputtering using a first indium oxide-based target in a first reactive gas that contains one, two, or three types selected from a group consisting of oxygen gas, hydrogen gas, and water vapor. Moreover, the second indium oxide-based thin film is formed in the second film forming step by performing sputtering using a second indium oxide-based target in a second reactive gas that contains one, two, or three types selected from a group consisting of oxygen gas, hydrogen gas, and water vapor, and that has a different composition from the first reactive gas.

Accordingly, with the aforementioned manufacturing method it is possible to laminate a plurality of refractive index layers with different refractive indices by using an indium oxide-based target, and as a result, it is possible to efficiently form an antireflection film that has the desired antireflection performance.

It is preferable that the hydrogen gas content of the second reactive gas differ from that of the first reactive gas.

It is preferable that the water vapor content of the second reactive gas differ from that of the first reactive gas.

It is preferable that the second indium oxide-based target be the same as the first indium oxide-based target.

It is preferable to perform the second film forming step in the same vacuum chamber as the first film forming step, with the first reactive gas being replaced with the second reactive gas.

It is preferable that the first indium oxide-based target and the second indium oxide-based target be tin-doped indium oxide-based targets, titanium-doped indium oxide-based targets, or zinc-doped indium oxide-based targets.

The antireflection film according to an aspect of the present invention is an antireflection film obtained by the aforementioned film forming method for an antireflection film, and is provided with a first indium oxide-based thin film and a second indium oxide-based thin film that is laminated on the first indium oxide-based thin film and that has a different refractive index than the first indium oxide-based thin film.

According to the aforementioned antireflection film, since the first indium oxide-based thin film and the second indium oxide-based thin film that is laminated on the first indium oxide-based thin film and that has a different refractive index than the first indium oxide-based thin film are provided, it is possible to provide an indium oxide-based antireflection film in which a plurality of refractive index layers with different refractive indices are laminated, and having the desired antireflection performance.

It is preferable that at least one of the first indium oxide-based thin film and the second indium oxide-based thin film have a specific resistance of 5×10² μΩ·cm or less.

The film forming device according to an aspect of the present invention is a film forming device that is used in the aforementioned film forming method for an antireflection film, and includes a vacuum container; a target holding unit that holds a target in this vacuum container; and a power supply that applies a sputtering voltage to the target, in which the vacuum container is provided with two or more of a hydrogen gas introducing unit, an oxygen gas introducing unit, and a water vapor introducing unit.

According to the aforementioned film forming device, since the vacuum container is provided with two or more of the hydrogen gas introducing unit, the oxygen gas introducing unit, and the water vapor introducing unit, it is possible to make the atmosphere when laminating a plurality of refractive index layers with different refractive indices on a substrate by a sputtering method using a target that consists of an indium oxide-based material a water vapor (H₂O) atmosphere that prevents the bonding of crystal lattices of In₂O₃. Thereby, it is possible to form an antireflection film that has the desired antireflection performance with one device using a target that consists of an indium oxide-based material.

Also, just by using one type of target that consists of an indium oxide-based material and adjusting the partial pressure of the oxygen gas, hydrogen gas or water vapor that are introduced, it is possible to readily form an antireflection film in which a plurality of refractive index layers with different refractive indices are laminated. Moreover, it is possible to form it at the conventional film formation speed or greater.

It is preferable that the target holding unit be provided with a magnetic field generating unit that causes the generation of a horizontal magnetic field of which the maximum value of the strength at the surface of the target is 600 Gauss or more.

Moreover, the vacuum container may be provided with a rotating body that rotates centered on the axis thereof and that detachably supports a plurality of substrates on the outer periphery surface thereof, and a plurality of target holding unit that each face one or more substrates among the plurality of substrates that are supported by the rotating body; and a plurality of types of films of different compositions may be formed on each substrate by performing sputtering using a target that is held by the target holding unit while causing the rotating body to rotate centered on the axis thereof.

### Effects of the Invention

Since the film forming method for an antireflection film of the aspect of the present invention has a first film forming step that forms the first indium oxide-based thin film by performing sputtering using a first indium oxide-based target in a first reactive gas that contains one, two, or three types selected from a group consisting of oxygen gas, hydrogen gas, and water vapor; and a second film forming step that forms on the first indium oxide-based thin film the second indium oxide-based thin film by performing sputtering using a second indium oxide-based target in a second reactive gas that contains one, two, or three types selected from a group consisting of oxygen gas, hydrogen gas, and water vapor, it is possible to readily laminate a plurality of refractive index layers with different refractive indices by using an indium oxide-based target. As a result, it is possible to efficiently form an antireflection film that has the desired antireflection performance.

Since the antireflection film according to the aspect of the present invention has a first indium oxide-based thin film and a second indium oxide-based thin film that is laminated on the first indium oxide-based thin film and that has a different refractive index than the first indium oxide-based thin film, it is possible to provide an indium oxide-based antireflection film in which a plurality of refractive index layers with different refractive indices are laminated, and having the desired antireflection performance.

Since the film forming device according to the aspect of the present invention has a vacuum container; a target holding unit that holds a target in this vacuum container; and a power supply that applies a sputtering voltage to the target, and the vacuum container is provided with two or more of a hydrogen gas introducing unit, an oxygen gas introducing unit, and a water vapor introducing unit, it is possible to change the atmosphere when laminating a plurality of refractive index layers with different refractive indices on a substrate by a sputtering method using a target that consists of an indium oxide-based material. Accordingly, it is possible to form an antireflection film that has the desired antireflection performance with one device using a target that consists of an indium oxide-based material.

Also, just by using one type of target that consists of an indium oxide-based material and adjusting the partial pressure of the oxygen gas, hydrogen gas or water vapor, it is possible to readily form an antireflection film in which a plurality of refractive index layers with different refractive indices are laminated. Moreover, it is possible to form it at the conventional film formation speed or greater.

### BRIEF DESCRIPTION OF THE DRAWINGS

FIG. 1 is a cross-sectional view that shows an example of an antireflection film according to a first embodiment of the present invention.

FIG. 2 is a cross-sectional view that shows a modification of the antireflection film according to the embodiment.

FIG. 3 is a schematic configuration drawing that shows an example of a sputtering device that is used in the formation of the antireflection film according to the embodiment.

FIG. 4 is a cross-sectional view that shows the essential portions of the film forming chamber that constitutes the sputtering device of FIG. 3.

FIG. 5 is a graph that shows the effect of H₂O gas (water vapor) in non-thermal film formation.

FIG. 6 is a graph that shows the simulation effect of the reflectance of an antireflection film.

FIG. 7 is a graph that shows the effect of H₂ gas in thermal film formation.

FIG. 8 is a cross-sectional view that shows the essential portions of a film forming chamber that constitutes the sputtering device that is used in the formation of the antireflection film according to the second embodiment of the present invention.

FIG. 9 is a schematic configuration drawing that shows the sputtering device according to a third embodiment of the present invention.

### EMBODIMENTS FOR CARRYING OUT THE INVENTION

Embodiments of the film forming method for an antireflection film, antireflection film, and film forming device according to the present invention shall be described.

Note that these embodiments will be described in detail for better comprehending the spirit of the invention, and unless otherwise stated, do not serve to limit the present invention.

### First Embodiment

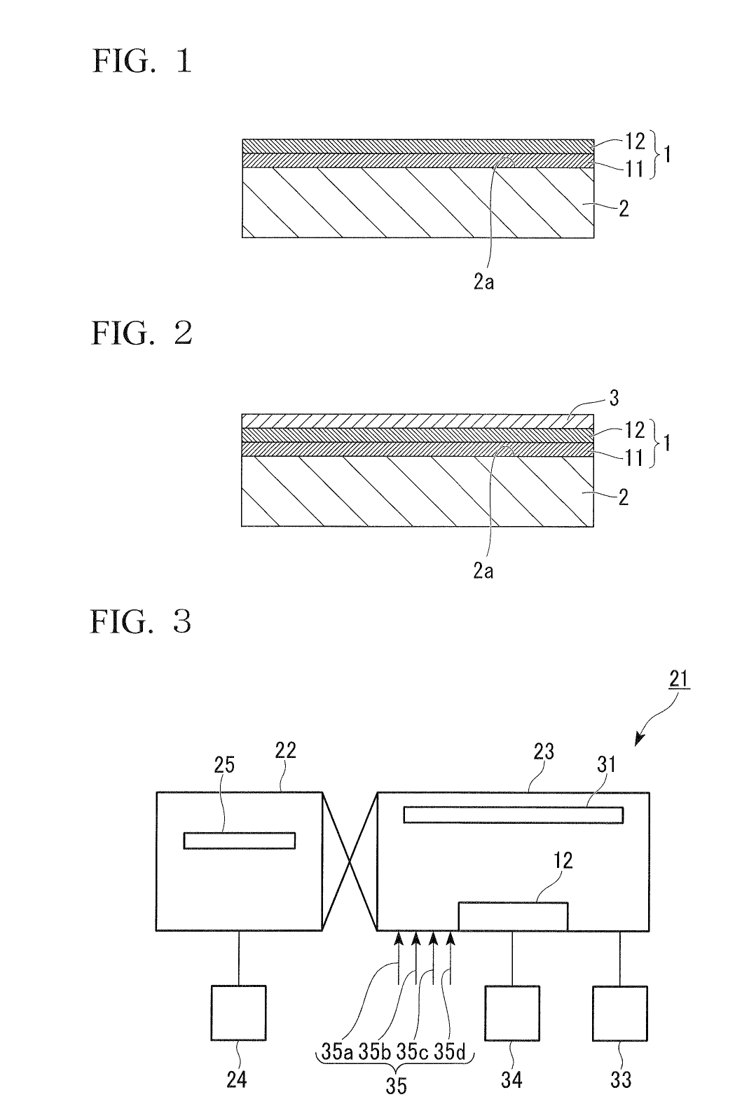

FIG. 1 is a cross-sectional drawing that shows an antireflection film according to the first embodiment of the present invention. This antireflection film 1 is formed on a surface 2a of a transparent substrate 2, and has a laminated structure. In the antireflection film 1, a plurality of indium oxide based thin films with different refractive indices, for example, a high refractive index transparent film 11 and a low refractive index transparent film 12, are laminated so that the refractive indices become successively smaller heading outward from the side of the surface 2a of the transparent substrate 2.

As these indium oxide-based thin films, for example, an indium oxide-based material that has In₂O₃—SnO₂, In₂O₃—TiO₂, In₂O₃—ZnO or the like as the chief component is suitably used.

For example, in the case of a laminated structure that uses tin-doped indium oxide (ITO), the low refractive index transparent film 12 in which the refractive index is for example 1.96 is obtained by performing film formation in an argon (Ar) gas atmosphere or an argon atmosphere that includes oxygen (Ar+O₂) with tin-doped indium oxide (ITO) serving as the target.

Also, the high refractive index transparent film 11 in which the refractive index is for example 2.25 is obtained by performing film formation in a hydrogen gas (H₂) and oxygen gas (O₂) atmosphere or water vapor (H₂O) atmosphere with the aforementioned tin-doped indium oxide (ITO) serving as the target.

The specific resistance of at least one of these indium oxide-based thin films, for example, at least one of the high refractive index transparent film 11 and the low refractive index transparent film 12, is preferably 5.0×10² μΩ·cm or less.

In this way, by making the specific resistance of at least one of the transparent films 11 and 12 5.0×10² μΩ·cm or less, it is possible to impart a function of a transparent electrically conductive film to this transparent film.

FIG. 2 is a cross-sectional drawing that shows a modification of the antireflection film according to this embodiment, and in the case of the specific resistance of the high refractive index transparent film 11 or the low refractive index transparent film 12 being high, lowering of the resistance is possible by antireflection design that increases the film thickness of the transparent films 11 and 12. By adopting such a constitution, it is possible to impart a function of a transparent electrically conductive film to the antireflection film 1.

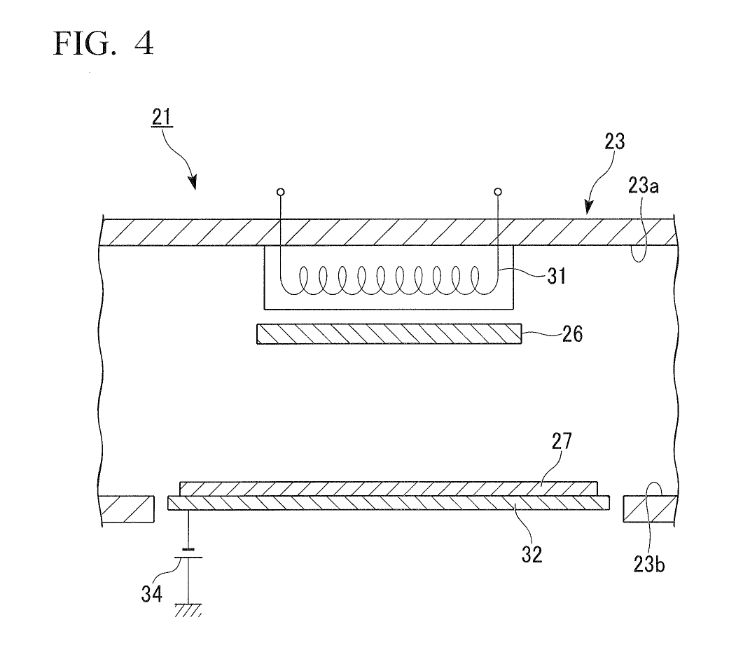

FIG. 3 is a schematic configuration drawing that shows the sputtering device (film forming device) that is used in the formation of the antireflection film according to the present embodiment. FIG. 4 is a cross-sectional drawing that shows the essential portions of the film forming chamber of the sputtering device.

This sputtering device 21 is an interback sputtering device, and for example is provided with a loading-in/taking-out chamber 22 that carries in/carries out substrates such as a glass substrate (not illustrated) and a film forming chamber (vacuum container) 23 that forms an indium oxide-based antireflection film on the aforementioned substrate. A rough vacuum evacuation unit 24 such as a rotary pump or the like that performs rough vacuum evacuation of this chamber is provided in the loading-in/taking-out chamber 22. Also, a substrate tray 25 for holding and conveying substrates is movably provided in the loading-in/taking-out chamber 22.

A heater 31 that heats a substrate 26 is vertically provided on one side surface 23a of the film forming chamber 23, and a cathode (target holding unit) 32 that holds a target 27 made of an indium oxide-based material and applies a desired sputtering voltage is vertically provided on the other side surface 23b. Moreover, a high vacuum evacuation unit 33 such as a turbo molecule pump that performs high vacuum evacuation of this chamber, a power supply 34 that applies a sputtering voltage to the target 27, and a gas introducing unit 35 that introduces a gas to this chamber are provided in the film forming chamber 23.

The cathode 32 is one that consists of a plate-shaped metallic plate, and fixes the target 27 by bonding (fixing) with a brazing material.

The power supply 34 applies a sputtering voltage to the target 27. This power supply 34 is not particularly limited, and it is possible to suitably use a direct current (DC) power supply, an alternating current (AC) power supply, a radio frequency (RF) power supply, and a DC power supply+RF power supply. Here, as the power supply 34, a direct current (DC) power supply (not illustrated) is used.

The gas introducing unit 35 is provided with a sputtering gas introducing unit 35a that introduces a sputtering gas such as Ar, a hydrogen gas introducing unit 35b that introduces hydrogen gas, an oxygen gas introducing unit 35c that introduces oxygen gas, and a water vapor introducing unit 35d that introduces water vapor.

unit 35, the hydrogen gas introducing unit 35b, the oxygen gas introducing unit 35c, and the water vapor introducing unit 35d may be selected for use as required. For example, the gas introducing unit 35 may be constituted with two unit, such as the gas introducing unit 35 that is constituted by the hydrogen gas introducing unit 35b and the oxygen gas introducing unit 35c, and the gas introducing unit 35 that is constituted by the hydrogen gas introducing unit 35b and the water vapor introducing unit 35d.

Next, the method of successively forming the indium oxide-based antireflection film 1 and the transparent electrically conductive film 3 on the transparent substrate 2 using the aforementioned sputtering device 21 shall be described.

Here, the description is given using an alkali-free glass substrate as a transparent substrate 2, and a two-layer structure that consists of an indium oxide-based material such as In₂O₃—SnO₂, In₂O₃—TiO₂, In₂O₃—ZnO as the antireflection film 1.

### <Formation of Antireflection Film>

### (a) Formation of High Refractive Index Transparent Film

In order to form the transparent film 11 with a high refractive index, the indium oxide-based target 27 is fixed by bonding with a brazing material to the cathode 32.

The indium oxide-based material serving as the target material that is used here includes for example a tin-doped indium oxide (ITO) in which tin oxide (SnO₂) is added 1.0 to 40.0 wt %, titanium-doped indium oxide in which titanium oxide (TiO₂) is added 0.1 to 10.0 wt %, and zinc-doped indium oxide in which zinc oxide (ZnO) is added 1.0 to 20.0 wt %.

Next, in the state of the substrate 26 being housed in the substrate tray 25 of the loading-in/taking-out chamber 22, the loading-in/taking-out chamber 22 and the film forming chamber 23 are subjected to rough vacuum evacuation by the rough vacuum evacuation unit 24. After the loading-in/taking-out chamber 22 and the film forming chamber 23 attain a predetermined vacuum degree, for example 0.27 Pa (2.0×10⁻³ Torr), the substrate 26 is conveyed from the loading-in/taking-out chamber 22 into the film forming chamber 23. This substrate 26 is arranged before the heater 31 in the state of being set to OFF, and this substrate 26 is made to face the target 27. This substrate 26 is heated by the heater 31 so as to enter a temperature range of room temperature to 600° C.

Next, the film forming chamber 23 is subjected to a high vacuum evacuation by the high vacuum evacuation unit 33. After the film forming chamber 23 attains a predetermined high vacuum degree, for example, 2.7×10⁻⁴ Pa (2.0×10⁻⁶ Torr), gas is introduced to this film forming chamber 23 in accordance with any of (1) to (5) given below:

(1) Introduction of H₂O gas (water vapor) by the water vapor introducing unit 35d [1 type of introduced gas].

(2) Introduction of H₂ gas by the hydrogen gas introducing unit 35b [1 type of introduced gas].

(3) Introduction of H₂O gas (water vapor) by the water vapor introducing unit 35d and introduction of H₂ gas by the hydrogen gas introducing unit 35b [two types of introduced gases].

(4) Introduction of H₂O gas (water vapor) by the water vapor introducing unit 35d and introduction of O₂ gas by the oxygen gas introducing unit 35c [two types of introduced gases].

(5) Introduction of H₂O gas (water vapor) by the water vapor introducing unit 35d, introduction of H₂ gas by the hydrogen gas introducing unit 35b, and introduction of O₂ gas by the oxygen gas introducing unit 35c [three types of introduced gases].

It is possible to make the interior of the film forming chamber 23 have any of the aforementioned five types of gas atmospheres, that is, the atmosphere of H₂O gas, the atmosphere of H₂ gas, the atmosphere of H₂O gas and H₂ gas, the atmosphere of H₂O gas and O₂ gas, and the atmosphere of H₂O gas, H₂ gas and O₂ gas.

Next, a sputtering voltage is applied to the target 27 by the power supply 34.

It is preferable that this sputtering voltage be 250 V or less. By lowering the discharge voltage, it is possible to manufacture a high density plasma with a high reactivity, and it is possible to cause the gas to bond as intended to the sputtering particles.

Above, a sputtering voltage may be used in which a high-frequency voltage is superimposed on a direct current voltage. By superimposing a high-frequency voltage on a direct current voltage, it is possible to further lower the discharge voltage.

Plasma is generated on the substrate 26 by the application of the sputtering voltage, and the ions of the sputtering gas such as Ar that are excited by this plasma collide with the target 27. From this collision, atoms that constitute the indium oxide-based material such as In₂O₃—SnO₂, In₂O₃—TiO₂, In₂O₃—ZnO are made to fly out from the target 27, whereby a transparent film that consists of the indium oxide-based material is formed on the substrate 26.

In this film forming process, the interior of the film forming chamber 23 becomes any of the aforementioned five types of gas atmospheres, that is, the atmosphere of H₂O gas, the atmosphere of H₂ gas, the atmosphere of H₂O gas and H₂ gas, the atmosphere of H₂O gas and O₂ gas, and the atmosphere of H₂O gas, H₂ gas and O₂ gas. Accordingly, if sputtering is performed in the aforementioned kind of atmosphere, the number of oxygen vacancies in the indium oxide crystal is controlled, and the transparent film 11 is obtained that has the predetermined high refractive index (for example, around 2.3) that is shifted to the high refractive index side, and the predetermined specific resistance (conductivity).

At this time, by satisfying the condition of the H₂ gas partial pressure being 0.5×10⁻⁵ Torr or more, and the O₂ gas partial pressure being 0.5×10⁻⁵ Torr or more, the transparent film 11 with a refractive index of around 2.3 is obtained.

Also, by satisfying the condition of the H₂ gas partial pressure being 0.5×10⁻⁵ Torr or more, and the H₂O gas partial pressure being 0.5×10⁻⁵ Torr or more, the transparent film 11 with a refractive index of around 2.3 is obtained.

By satisfying the condition of the H₂O gas partial pressure being 1.0×10⁻⁵ Torr or more, the transparent film 11 with a refractive index of around 2.3 is obtained.

In this way, by making the interior of the film forming chamber 23 become any of the aforementioned five types of gas atmospheres, that is, the atmosphere of H₂O gas, the atmosphere of H₂ gas, the atmosphere of H₂O gas and H₂ gas, the atmosphere of H₂O gas and O₂ gas, and the atmosphere of H₂O gas, H₂ gas and O₂ gas, the specific resistance (conductivity) of the obtained transparent film 11 also changes. By adjusting the partial pressure of the H₂O gas, the partial pressure of the H₂ gas and the O₂ gas, the partial pressure of the H₂ gas and the H₂O gas, the partial pressure of the O₂ gas and the H₂O gas, and the partial pressure of the O₂ gas, the H₂ gas, and the H₂O gas, the oxygen vacancies are optimized, whereby it is possible to obtain the transparent film 11 that has conductivity. In the case of conductivity not being required, it may be otherwise provided the other conditions are satisfied.

In this way, the transparent film 11 with the high refractive index that is formed in the atmosphere of H₂O gas, H₂ gas+O₂ gas, H₂ gas+H₂O gas, O₂ gas+H₂O gas, or O₂ gas+H₂ gas+H₂O gas may also serve as a transparent electrically conductive film since the specific resistance is low. In this case, the transparent electrically conductive film 3 is not required.

### (b) Formation of Low Refractive Index Transparent Film

In the state of the indium oxide-based target 27 being left as is in the film forming chamber 23, by introducing Ar gas from the sputtering gas introducing unit 35a to the film forming chamber 23, or by introducing Ar gas and O₂ gas by the sputtering gas introducing unit 35a and the oxygen gas introducing unit 35c, the interior of the film forming chamber 23 becomes an Ar gas atmosphere or an Ar gas atmosphere that includes O₂ gas (Ar+O₂).

When forming a low refractive index transparent film, the same indium oxide-based target 27 that was used for the high refractive index transparent film is used to make the atmosphere during film formation an Ar gas atmosphere or an Ar gas atmosphere that includes O₂ gas (Ar+O₂). Thereby, the desired low refractive index transparent film is constituted.

In this film formation process, the atmosphere in the film forming chamber 23 becomes an Ar gas atmosphere or an Ar gas atmosphere that includes O₂ gas (Ar+O₂). If sputtering is performed in this atmosphere, the number of oxygen vacancies in the indium oxide crystal is controlled, and the transparent film 12 is obtained that has the desired low refractive index (for example around 2.0) and the desire specific resistance (conductivity).

Note that in the case of having shifted the refractive index of this transparent film 12, the atmosphere during film formation should be changed from an Ar gas atmosphere or an Ar gas atmosphere that includes O₂ gas (Ar+O₂) to an atmosphere to which H₂ gas and/or H₂O gas (water vapor) is added to Ar gas or Ar gas that includes O₂ gas.

to the film forming chamber 23 H₂ gas by the hydrogen gas introducing unit 35b or introducing to the film forming chamber 23 H₂O gas (water vapor) by the water vapor introducing unit 35d.

Note that since H₂ gas and/or H₂O gas is contained in this film forming chamber 23, it is possible to control the refractive index and specific resistance (conductivity) of the obtained transparent film by controlling the respective partial pressures of the H₂ gas, H₂O gas (water vapor), and Ar+O₂ gas.

Next, the method of forming the transparent electrically conductive film 3 on the transparent film 12 with a high specific resistance and low refractive index shall be described.

### <Formation of Transparent Electrically Conductive Film>

In the formation of the transparent electrically conductive film 3, the aforementioned indium oxide-based target 27 is used, and the temperature of the substrate 26 is put in a temperature range of 100° C. to 600° C., similarly to the aforementioned antireflection film. Also, sputtering gas such as Ar is introduced by a sputtering gas introducing unit 15a to the film forming chamber 23, and using one, two or three of a hydrogen gas introducing unit 15b, an oxygen gas introducing unit 15c, and a water vapor introducing unit 15d, one, two, or three types of gases selected from the group consisting of hydrogen gas, oxygen gas and water vapor is/are introduced.

By doing so, the substrate 26 is obtained in which the indium oxide-based transparent electrically conductive film 3 is formed having low specific resistance and good transparency to visible light rays.

Next, the experimental results conducted by the inventors shall be described for the method of manufacturing the indium oxide-based transparent electrically conductive film and antireflection film according to the present embodiment.

A In₂O₃-10 wt % SnO₂ (ITO) target measuring 5 inches by 16 inches was fixed by a brazing material to a parallel plate-type cathode 32 that applies a DC voltage. Next, an alkali-free glass substrate is placed in the loading-in/taking-out chamber 22, and a rough vacuum is achieved in the loading-in/taking-out chamber 22 using the rough vacuum evacuation unit 24. Next, this alkali-free glass substrate is conveyed to the film forming chamber 23 that is subjected to a high vacuum evacuation by the high vacuum evacuation unit 33, and it is disposed opposite the ITO target.

Next, after Ar gas has been introduced by the gas introducing unit 35 to the film forming chamber 23 at a pressure of 5 mTorr, H₂O gas is introduced so that the partial pressure thereof becomes 5×10⁻⁵ Torr. Also, in another example, after Ar gas has been introduced to the film forming chamber 23 at a pressure of 5 mTorr, O₂ gas is introduced so that the partial pressure thereof becomes 2×10⁻⁵ Torr. In the aforementioned case of having introduced H₂O gas and in the aforementioned case of having introduced O₂ gas, by applying 1 kW of power to the cathode 32 with the power supply 34, the ITO target that is attached to the cathode 32 is sputtered, and an ITO film is deposited on the alkali-free glass substrate.

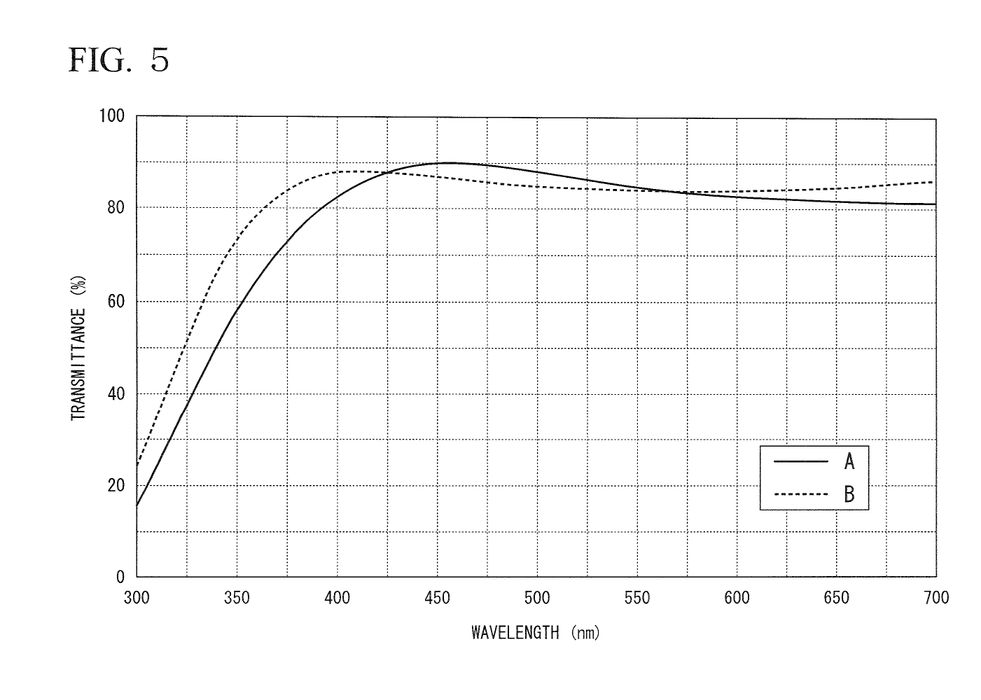

FIG. 5 is a graph that shows the H₂O gas (water vapor) effect in the indium oxide-based transparent electrically conductive film that is annealed (240° C.×1 hr) in the atmosphere after being formed without heating. In the same graph, A indicates the transmittance of the indium oxide-based transparent electrically conductive film in the case of having introduced H₂O gas to a partial pressure of 5×10⁻⁵ Torr, and B indicates the transmittance of the indium oxide-based transparent electrically conductive film in the case of having introduced O₂ gas to a partial pressure of 2×10⁻⁵ Torr.

In the case of having introduced H₂O gas, the thickness of the transparent electrically conductive film is 100.0 nm, and the specific resistance is 1400 μΩcm.

In the case of having introduced O₂ gas, the thickness of the transparent electrically conductive film is 99.1 nm, and the specific resistance is 200 μΩcm.

According to FIG. 5, it is evident that by introducing water vapor (H₂O), the peak wavelength of the transmittance can be changed without changing the film thickness.

Also, in the case of having introduced a large quantity of water vapor, it is evident that the specific resistance is high, and the resistance to degradation is great, but it can be applied to an optical member in which low resistance is not required such as an antireflection film.

Moreover, by repeating the film formation while changing between non-introduction and introduction of water vapor, or the introduction amount, it is evident that an optical device having a structure in which a plurality of layers of mutually different refractive indices are laminated is obtained with one target.

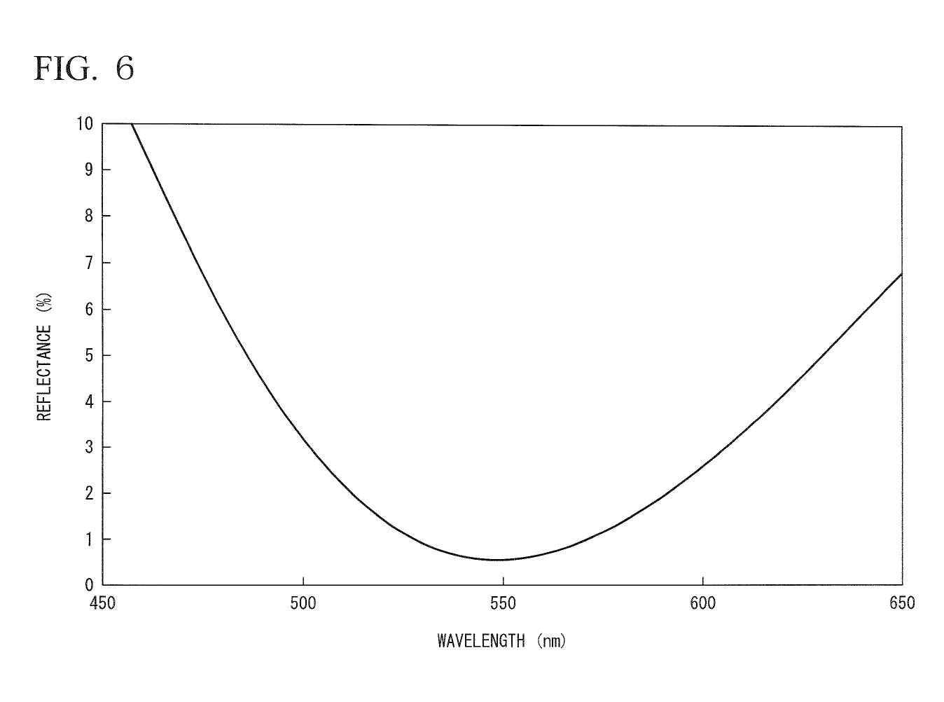

FIG. 6 is a graph that shows the simulation result of the reflectance of an antireflection film of which optical design is performed using the refractive indices calculated from the A and B spectrums in FIG. 5.

Here, the values of the peak wavelength (2) 388 nm and the film thickness (d) 99.1 nm found from the B spectrum in FIG. 5 are simply substituted into the equation 2nd=mλ (in the equation, d is the film thickness, λ, is the wavelength, n is the refractive index, and m is an integer), and the refractive index (n) of the low refractive index transparent film calculated assuming m=1 was 1.96.

On the other hand, the values of the peak wavelength (2) 450 nm and the film thickness (d) 100.0 nm found from the A spectrum in FIG. 5 are simply substituted into the equation “2nd=mλ” (in the equation, d is the film thickness, λ, is the wavelength, n is the refractive index, and m is an integer), and the refractive index (n) of the high refractive index transparent film calculated assuming m=1 was 2.25.

Next, a low refractive index transparent film with a refractive index (n) of 1.96 was formed on a glass substrate so as to have a film thickness (d) of 74.9 nm, and a high refractive index transparent film with a refractive index (n) of 2.25 was formed on the low refractive index transparent film so as to have a film thickness (d) of 55.2 nm.

According to FIG. 6, it was found that the reflectance of the antireflection film at the wavelength (λ) of 550 nm was 0.532%, and so it was evident that it is possible to consecutively form antireflection films having a laminated structure using one target.

Next, an ITO film was deposed on an alkali-free glass substrate in the same manner as above.

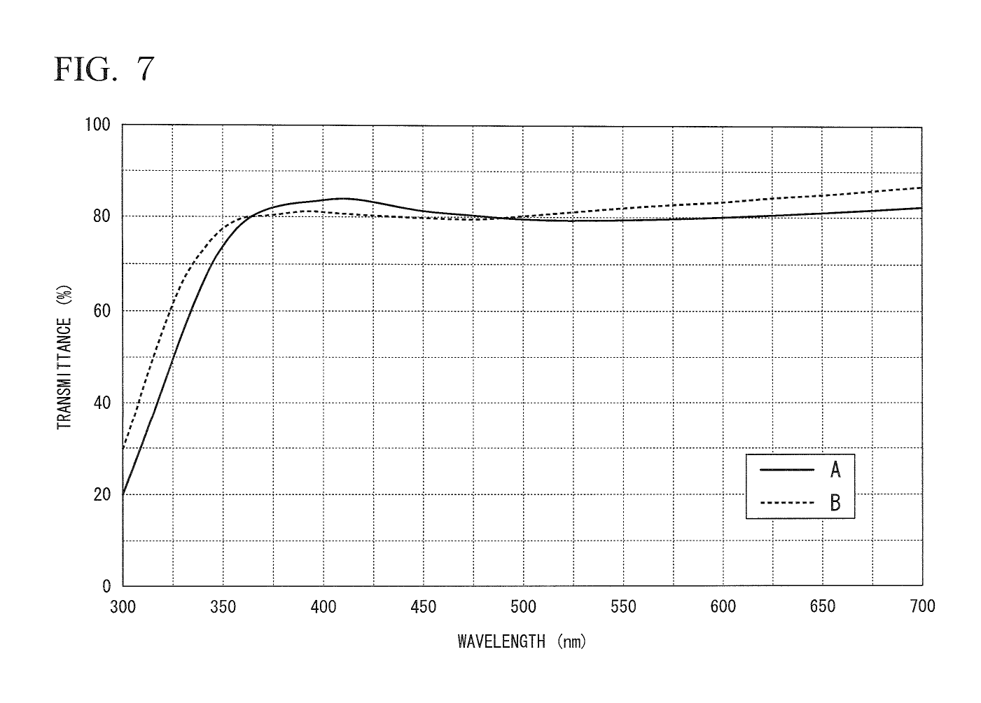

FIG. 7 is a graph that shows the effect of H₂ gas. In the figure, A indicates the transmittance of the indium oxide-based conductive film in the case of having introduced H₂ gas so as to become 2×10⁻⁵ Torr and O₂ gas until 5×10⁻⁵ Torr, and B indicates the transmittance of the indium oxide-based conductive film in the case of having introduced O₂ gas to a partial pressure of 2×10⁻⁵ Torr. Note that in the aforementioned, a parallel plate-type cathode that applies a DC voltage was used.

In the case of having introduced H₂ gas+O₂ gas, the thickness of the transparent electrically conductive film is 75.0 nm, and the specific resistance is 1700 μΩcm.

Also, in the case of having introduced O₂ gas, the thickness of the transparent electrically conductive film is 74.9 nm, and the specific resistance is 240 μΩcm.

According to FIG. 7, even for the introduction of H₂ gas+O₂ gas, it is evident that the same effect is obtained as the case of the introduction of H₂O gas.

According to the method of forming the antireflection film of the present embodiment, since sputtering is performed in a reactive gas atmosphere that includes 1 type, two types, or three types that is/are selected from the group consisting of hydrogen gas, oxygen gas, and water vapor, it is possible to easily form an indium oxide-based antireflection film with excellent transparency to visible light rays.

According to the film forming device of the present embodiment, since the gas introducing unit 35 has the sputtering gas introducing unit 35a that introduces a sputtering gas such as Ar, the hydrogen gas introducing unit 35b that introduces hydrogen gas, the oxygen gas introducing unit 35c that introduces oxygen gas, and the water vapor introducing unit 35d that introduces water vapor, by controlling the sputtering gas introducing unit 35a, the hydrogen gas introducing unit 35b, the oxygen gas introducing unit 35c, and the water vapor introducing unit 35d, it is possible to produce a water vapor atmosphere that prevents the bonding of crystal lattices of In₂O₃ when forming the indium oxide-based antireflection film 1.

Accordingly, just by improving a portion of a conventional film forming device, it is possible to form an indium oxide-based antireflection film.

Note that the antireflection film 1 of the present embodiment is an antireflection film with a two-layer structure in which the high refractive index transparent film 11 and the low refractive index transparent film 12 are successively formed on the surface 2a of the transparent substrate 2, but the lamination structure of the antireflection film 1 is not limited to the aforementioned two-layer structure. It may be a multi-layer structure of three layers or more so as to satisfy the antireflection performance of the required antireflection film. For example, it may be a multi-layer structure in which the high refractive index transparent film 11 and the low refractive index transparent film 12 are repeatedly formed a plurality of times.

### Second Embodiment

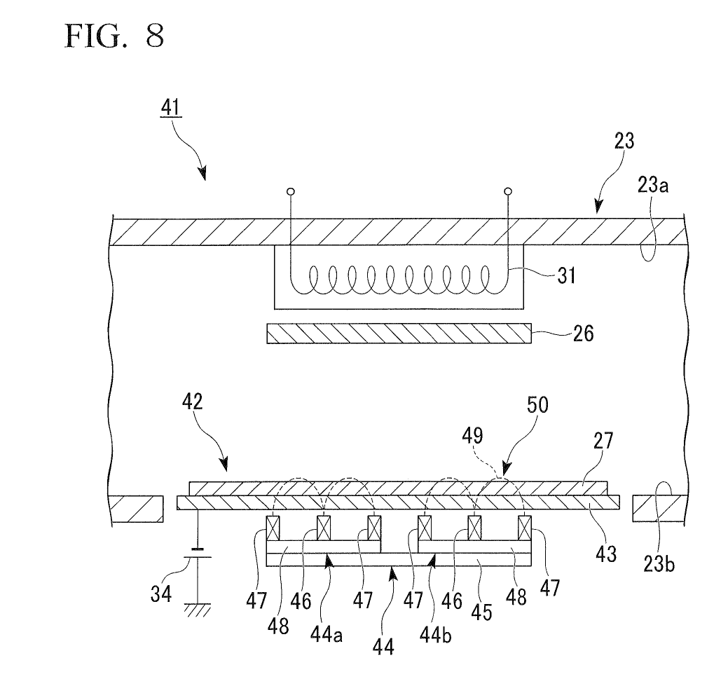

FIG. 8 is a cross-sectional drawing that shows the essential portions of a film forming chamber of an interback-type magnetron sputtering device (film forming device) that is used for forming an antireflection film according to the second embodiment of the present invention.

This magnetron sputtering device 41 differs from the aforementioned sputtering device 21 on the point of a sputtering cathode mechanism (target holding unit) 42 that holds the target 27 made of an indium oxide-based material and generates a desired magnetic field being vertically provided on the one side surface 23b of the film forming chamber 23.

The sputtering cathode mechanism 42 is provided with a back plate 43 that bonds (fixes) the target 27 with a brazing material, and a magnetic circuit (magnetic field generating unit) 44 that is disposed along the rear surface of the back plate 43. The magnetic circuit 44 generates a horizontal magnetic field on the surface of the target 27, and a plurality of magnetic circuit units (two are shown in FIG. 8) 44a and 44b are coupled and unified by a bracket 45. The magnetic circuit units 44a and 44b are respectively provided with a first magnet 46 and a second magnet 47 whose polarities at the surface of the back plate 43 side mutually differ, and a yoke 48 on which they are fitted.

In this magnetic circuit 44, a magnetic field that is expressed by magnetic lines 49 is generated by the first magnet 46 and the second magnet 47 whose polarities mutually differ on the back plate 43 side. Thereby, a position 50 appears at which the vertical magnetic field becomes 0 (the horizontal magnetic field is a maximum) at a region corresponding to the space between the first magnet 46 and the second magnet 47 on the surface of the target 27. Since high-density plasma is generated at this position 50, it is possible to improve the film formation speed.

The maximum value of the strength of the horizontal magnetic field on the surface of the target 27 is preferably 600 Gauss or more. By making the maximum value of the strength of the horizontal magnetic field 600 Gauss or more, it is possible to lower the discharge voltage.

Even in the magnetron sputtering device 41 of the present embodiment, it is possible to obtain the same effect as the sputtering device 21 of the first embodiment.

Moreover, since the sputtering cathode mechanism 42 that generates a desired magnetic field is vertically provided on one side surface 23b of the film forming chamber 23, by making the sputtering voltage 250 V or less, and making the maximum value of the horizontal magnetic field strength on the surface of the target 27 600 Gauss or more, it is possible to produce a high-density plasma having high reactivity. As a result, it is possible to make the gas bond as intended to the sputtering particles, and form the indium oxide-based antireflection film.

### Third Embodiment

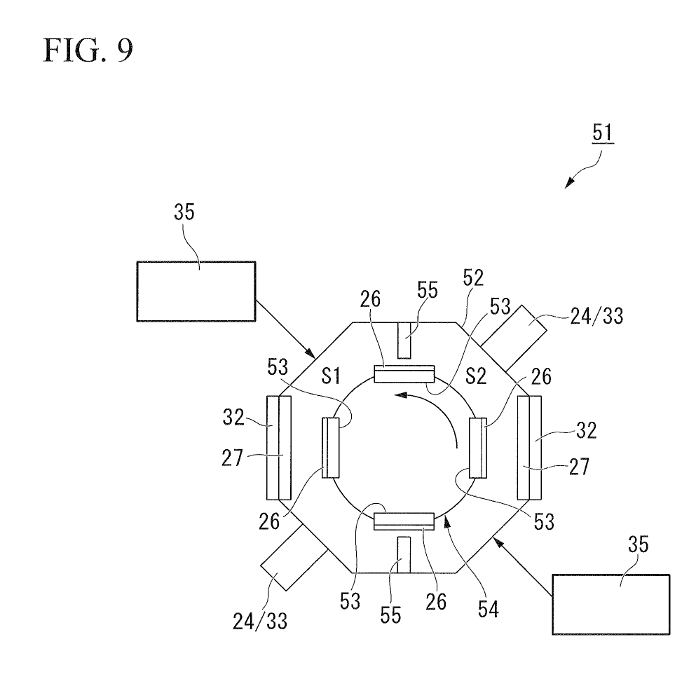

FIG. 9 is a schematic configuration drawing that shows a carousel-type sputtering device (film forming device) according to the third embodiment of the present invention.

In a film forming chamber (vacuum container) 52 of the sputtering device 51, a rotating body 54 that rotates centered on the center axis of this film forming chamber 52 is provided. On the outer periphery surface of the rotating body 54, a substrate holder 53 (four are shown in FIG. 9) that detachably supports a plurality of substrates 26 is provided. Moreover, a plurality of cathodes 32 (2 are shown in FIG. 9) that hold the target 27 made of an indium oxide-based material and apply a desired sputtering voltage are provided on the internal surface of the film forming chamber 52. When the rotating body 54 is made to rotate about the axis thereof, and the substrate holder 53 is made to stop at a position facing the cathode 32, the substrate 26 that is supported by the substrate holder 53 of the rotating body 54 opposes the target 27 that is held by the cathode 32.

A partition plate 55 that divides the inside of the film forming chamber 52 into two sputtering regions S₁ and S₂ is provided in the chamber. The rough vacuum evacuation unit 24 and the high vacuum evacuation unit 33 are provided in these two sputtering regions S₁ and S₂, respectively. Moreover, the gas introducing unit 35 that has the sputtering gas introducing unit 35a that introduces a sputtering gas such as Ar, the hydrogen gas introducing unit 35b that introduces hydrogen gas, the oxygen gas introducing unit 35c that introduces oxygen gas, and the water vapor introducing unit 35d that introduces water vapor is provided in each of these two sputtering regions S₁ and S₂.

In the film forming chamber 52, by performing either one or both of introducing H₂O gas (water vapor) and introducing H₂ gas that includes O₂ gas (H₂+O₂) to the sputtering region S₁ by the gas introducing unit 35, it is possible to make the interior of this sputtering region S₁ an H₂ gas atmosphere that includes H₂O gas (H₂+H₂O). By performing sputtering in this atmosphere, the high refractive index transparent film 11 that has the desired high refractive index is formed on the substrate 26.

Next, by causing the rotating body 54 to rotate centered on the axis thereof, the substrate 26 on which the high refractive index transparent film 11 is formed is moved to the sputtering region S₂. By introducing O₂ gas to this sputtering region S₂ with the gas introducing unit 35, the interior of this sputtering region S₂ is made an O₂ gas atmosphere. By performing sputtering in this atmosphere, the low refractive index transparent film 12 that has the desired low refractive index is formed on the transparent film 11 with the high refractive index.

From the above, by using the aforementioned sputtering device 51, it is possible to form the indium oxide-based antireflection film 1 according to the aforementioned first embodiment.

Note that in the case of a device in which light from a glass surface is incident, the low refractive index transparent film 12 with the desired low refractive index should be formed on the high refractive index transparent film 11.

Also, in this film forming chamber 52, it is also possible to form the indium oxide-based antireflection film 1 according to the aforementioned first embodiment by forming the high refractive index transparent film 11 on the substrate 26 by performing either one or both of the introduction of H₂O gas and the introduction of H₂ gas that includes O₂ gas (H₂+O₂) to the totality of the sputtering regions S₁ and S₂ with the gas introducing unit 35 and sputtering by causing the substrate 26 to rotate in this atmosphere; and next by forming the low refractive index transparent film 12 by performing the introduction of O₂ gas to the totality of the sputtering regions S₁ and S₂ with the gas introducing unit 35 and sputtering by causing the substrate 26 to rotate in this altered atmosphere.

It is possible to obtain the same effect as the sputtering device 21 according to the first embodiment even by using the sputtering device 51 of the present embodiment.

Moreover, a rotating body 64 that rotates centered on the center axis of this film forming chamber 52 and that has a substrate holder 63 that detachably supports a plurality of the substrates 26 is provided in the film forming chamber 52. Moreover, a plurality of cathodes 32 that hold the target 27 made of an indium oxide-based material is provided on the inside surface of the film forming chamber 52. Accordingly, by causing the rotating body 54 to which the substrates 26 are attached to rotate centered on the axis thereof, it is possible to form a multi-layer structure film in different atmospheres. Accordingly, this is suited to the case of repeatedly forming a multilayer film.

### INDUSTRIAL APPLICABILITY

The present invention can provide a film forming method for an antireflection film that is capable of obtaining an indium oxide-based antireflection film that has the desired antireflection performance and that functions as a transparent electrically conductive film by performing sputtering in the same film forming chamber without involving the bringing in of a substrate to a film forming chamber that performs sputtering and the bringing out of the substrate from the same film forming chamber. Also, it is possible to provide an indium oxide-based antireflection film that has the desired antireflection performance and that functions as a transparent electrically conductive film.

Moreover, it can provide a film forming device that is capable of forming with one device an antireflection film in which a plurality of refractive index layers with mutually differing refractive indices are laminated.

### DESCRIPTION OF REFERENCE NUMERALS

1 Antireflection film
2 Transparent substrate
2a Surface
3 Transparent electrically conductive film
11 Transparent film with high refractive index
12 Transparent film with low refractive index
21 Sputtering device
22 Loading-in/taking-out chamber
23 Film forming chamber
24 Rough vacuum evacuation unit
25 Substrate tray
26 Substrate
27 Target
28 Heater
31 Cathode
33 High vacuum evacuation unit

What is claimed is:

1. A film forming method for an antireflection film that has a first indium oxide-based thin film and a second indium oxide-based thin film that is laminated on the first indium oxide-based thin film, the method comprising:
a first film forming step that forms the first indium oxide-based thin film by performing sputtering using a first indium oxide-based target in a first reactive gas that contains one, two, or three types selected from a group consisting of oxygen gas, hydrogen gas, and water vapor; and
a second film forming step that forms on the first indium oxide-based thin film the second indium oxide-based thin film by performing sputtering using a second indium oxide-based target in a second reactive gas that contains one, two, or three types selected from a group consisting of oxygen gas, hydrogen gas, and water vapor, and that has a different composition from the first reactive gas.

2. The film forming method for an antireflection film according to claim 1, wherein the hydrogen gas content of the second reactive gas differs from that of the first reactive gas.

3. The film forming method for an antireflection film according to claim 1, wherein the water vapor content of the second reactive gas differs from that of the first reactive gas.

4. The film forming method for an antireflection film according to claim 1, wherein the second indium oxide-based target is the same as the first indium oxide-based target.

5. The film forming method for an antireflection film according to claim 1, wherein the second film forming step is performed in the same vacuum chamber as the first film forming step, with the first reactive gas being replaced with the second reactive gas.

6. The film forming method for an antireflection film according to claim 1, wherein the first indium oxide-based target and the second indium oxide-based target are tin-doped indium oxide-based targets, titanium-doped indium oxide-based targets, or zinc-doped indium oxide-based targets.

7. An antireflection film that is obtained by the film forming method for an antireflection film according to claim 1, comprising:
a first indium oxide-based thin film; and
a second indium oxide-based thin film that is laminated on the first indium oxide-based thin film and that has a different refractive index than the first indium oxide-based thin film.

8. The antireflection film according to claim 7, wherein at least one of the first indium oxide-based thin film and the second indium oxide-based thin film has a specific resistance of 5×10² μΩ·cm or less.

9. A film forming device that is used in the film forming method for an antireflection film according to claim 1, comprising:
a vacuum container;
a target holding unit that holds a target in this vacuum container; and
a power supply that applies a sputtering voltage to the target, wherein
the vacuum container comprises two or more of a hydrogen gas introducing unit, an oxygen gas introducing unit, and a water vapor introducing unit.

10. The film forming device according to claim 9, wherein the target holding unit comprises a magnetic field generating unit that causes the generation of a horizontal magnetic field of which the maximum value of the strength at the surface of the target is 600 Gauss or more.

11. The film forming device according to claim 9, wherein the vacuum container comprises a rotating body that rotates centered on the axis thereof and that detachably supports a plurality of substrates on the outer periphery surface thereof, and a plurality of target holding unit that each face one or more substrates among the plurality of substrates that are supported by the rotating body; and
a plurality of types of films of different compositions is formed on each substrate by performing sputtering using a target that is held by the target holding unit while causing the rotating body to rotate centered on the axis thereof.
